(19) United States
(12) Patent Application Publication
(10) Pub. No.: US 2002/0144208 A1
(43) Pub. Date: Oct. 3, 2002

(54) Systems and methods for enabling computation of CRC' s N-bit at a time

(75) Inventors: Rene Gallezot, La Colle sur Loup (FR); Rene Glaise, Nice (FR)

Correspondence Address: IBM CORPORATION, PO BOX 12195, DEPT 9CCA, BLDG 002, RESEARCH TRIANGLE PARK, NC, 27709, US

(73) Assignee: International Business Machines Corporation, Armonk, NY (US)

(21) Appl. No.: 10/084,543

(22) Filed: Feb. 27, 2002

(30) Foreign Application Priority Data
Mar. 30, 2001 (EP) 01480026.2

(51) Int. Cl. H03M 13/00

(52) U.S. Cl. 714/781

(57) ABSTRACT

A general way of performing a Cyclic Redundancy Check (CRC) calculation, N-bit at a time, is disclosed. CRC calculation is based on a generator polynomial G(x) of degree d so that all results always fit a d-bit wide Field Check Sequence (FCS). The generator polynomial allows forming a multiplicative cyclic group comprised of d-bit wide binary vectors. The iterative calculation method assumes that each new N-bit chunk of data bits, picked from the binary string of data bits, is divided, modulo the generator polynomial G(x), so that to obtain a d-bit wide division result while a current value of the d-bit wide FCS is displaced in the multiplicative cyclic group, of a value corresponding to N. Then, the d-bit wide division result and the displaced d-bit wide FCS are added to become the new current FCS. The above steps are re-executed until no data bits are left thus, getting the final result of the CRC calculation which can be used either for checking or generation of FCS. The method of the invention allows a forward (from MSB—Most Significant Bit) or backward (from LSB—Least Significant Bit) calculation of CRC's. The invention also provides for an automatic generation of the logic necessary to actually carry out the calculations thus, does not assume any particular skill on CRC's when used. It applies, irrespective of the degree of the generator polynomial in use (d) and whatever value of N is picked.

### FIELD OF THE INVENTION

The present invention relates generally to the calculation of Cyclic Redundancy Check (CRC) codes and is more particularly concerned with a general method for computing N-bit at a time, which applies irrespective of the relative value of N versus the degree of the CRC generator polynomial in use and for which the logic can be derived automatically.

### BACKGROUND OF THE INVENTION

Cyclic Redundancy Checking (CRC) has long been, and still remains, the technique of choice for verifying the integrity of messages transmitted over communications networks. As the name suggests, redundant information, under the form of a digest computed on the entire message, is appended at the end of each transmitted message so as the recipient is made capable of verifying that the message has not been corrupted en route. At least, recipient can be assured that, if errors have occurred that stayed within the boundaries of the error model for which CRC was devised then, they will be, for sure, detected. Recipient does this checking by performing the same calculation as it was done by the source. If both results match then, received message is assumed to have not been corrupted and therefore, can be safely acted on. Recipient knows that the result of calculation is the same just because what was computed by the source was transmitted with the message under the form of a (redundant) Field Check Sequence or FCS which can be compared to the calculation performed locally. This process is sometimes referred to as, forward error checking (FEC) since enough information is forwarded with what is transmitted to enable the receiver to detect that errors have occurred and, sometimes, to correct some of them.

Most communications protocols and standards, if not all, make use of CRC's. To each CRC corresponds a generator polynomial G(x). And, to specify the way a particular CRC should be used, protocols or standards always explain and describe their CRC through a particular model based on a Linear Feedback Sift Register or LFSR. An example of this can be found in “Fiber Distributed Data Interface (FDDI)”, ISO 9314-2, International Organization for Standardization, Geneva, Switzerland, 1989. Yet simple this approach (with this approach one may just ignore the mathematics on which CRC is actually based which is generally considered as an advantage) tends, however, to favor a bit-wise computation of CRC's similar to LFSR structure. If this kind of implementation used to be a valid solution to the actual implementation of CRC's the dramatic increase in the speed of the communications lines, now commonly measured in gibabits or tenth of gigabits per second, renders the one-bit-at-a-time type of processing totally inadequate. Even byte-wise solutions that have been often proposed since the eighties, see e.g., “Byte Wise CRC Calculation”, IEEE Micro, pp. 40-46, by A. PEREZ, June 1983, are insufficient nowadays. Actually, current technology e.g., CMOS, have not seen their speed improved as dramatically (as compared to optical line speed) thus, forcing designer to process more bits in parallel in an attempt to cope with the huge throughput, result of the use of those telecommunications lines especially, when they converge e.g., at a switching node of a communications network for being dispatched.

### OBJECTS OF THE INVENTION

Thus, it is a broad object of the invention to disclose a general method enabling the computation of CRC's N-bit at a time.

It is a further object of the invention to permit that method fits whatever CRC generator polynomial is specified and, whatever number of bits have to be processed at a time (so as to cope with overall required data throughput).

It is another object of the invention to permit forward (from most significant bit) and backward (from least significant bit) computation of CRC's so as any mode of transmission or storage can readily be accommodated.

It is yet another object of the invention to allow an automatic generation of the logic necessary to carry out the computation according to the invention i.e., without requiring any particular skill on the mathematics of the CRC's.

Further objects, features and advantages of the present invention will become apparent to the ones skilled in the art upon examination of the following description in reference to the accompanying drawings. It is intended that any additional advantages be incorporated herein. SUMMARY OF THE INVENTION

A method and systems are disclosed for performing a Cyclic Redundancy Check (CRC) calculation, N-bit at a time, over a binary string of data bits. The CRC calculation is based on a generator polynomial G(X) of degree d. It has intermediate and final results fitting a d-bit wide Field Check Sequence (FCS). The generator polynomial allows to form a multiplicative cyclic group comprised of d-bit wide binary vectors. The iterative calculation method assumes that, at each loop, a new N-bit chunk of data bits is picked from the binary string of data bits. It is divided, modulo the generator polynomial G(x), to obtain a d-bit wide division result. Meanwhile, a current value of the d-bit wide FCS, considered as one of the d-bit wide binary vectors, is displaced in the multiplicative cyclic group, of a value corresponding to N. Then, the d-bit wide division result and the displaced d-bit wide FCS are added modulo two and used to update the FCS. The above steps are re-executed until no data are left of the binary string of data bits thus, getting the final result of the CRC calculation which can be used either for checking a message already including a FCS or for the generation of this FCS. The method of the invention allows a forward (from MSB) or backward (from LSB) calculation of CRC's.

The invention also discloses methods and systems for deriving automatically the logic necessary to actually carry out the above calculations thus, does not assume any particular skill on CRC's from those practicing the invention. It applies, irrespective of the degree (d) of the generator polynomial in use, and whatever value of N is picked.

### BRIEF DESCRIPTION OF THE DRAWINGS

FIG. 1 shows a Field Check Sequence (FCS) appended to a message and computed with generator polynomial G(x).

FIG. 2 shows the logic operators needed to carry out the invention.

FIG. 3 is an example of an addition/substraction done according to the rules of the algebra for CRC.

FIG. 4 depicts how a multiplicative group can be build.

FIG. 5 shows the computational model for a forward calculation of CRC's N-bit at a time.

FIG. 6 is an example of the structure of the multiplier and divider needed for a forward calculation.

FIG. 7 shows the computational model for a backward calculation of CRC's N-bit at a time.

FIG. 8 is an example of the structure of the multiplier and divider needed for a backward calculation.

FIG. 9 explain how the last vector of a multiplicative group can be deduced from G(x).

FIG. 10 is an example of implementation of the multiplier and divider for a forward computation.

FIG. 11 shows the steps of the method for computing N-bit at a time according to the invention.

FIG. 12 shows the steps of the method for generating the logic necessary to carry out a forward CRC computation.

FIG. 13 shows the steps of the method for generating the logic necessary to carry out a backward CRC computation.

FIG. 14 depicts a system including a processor executing instructions for calculating CRC per the invention.

FIG. 15 depicts a system including a work station used to generate automatically the logic necessary to carry out CRC calculation per the invention.

### DETAILED DESCRIPTION OF THE PREFERRED EMBODIMENT

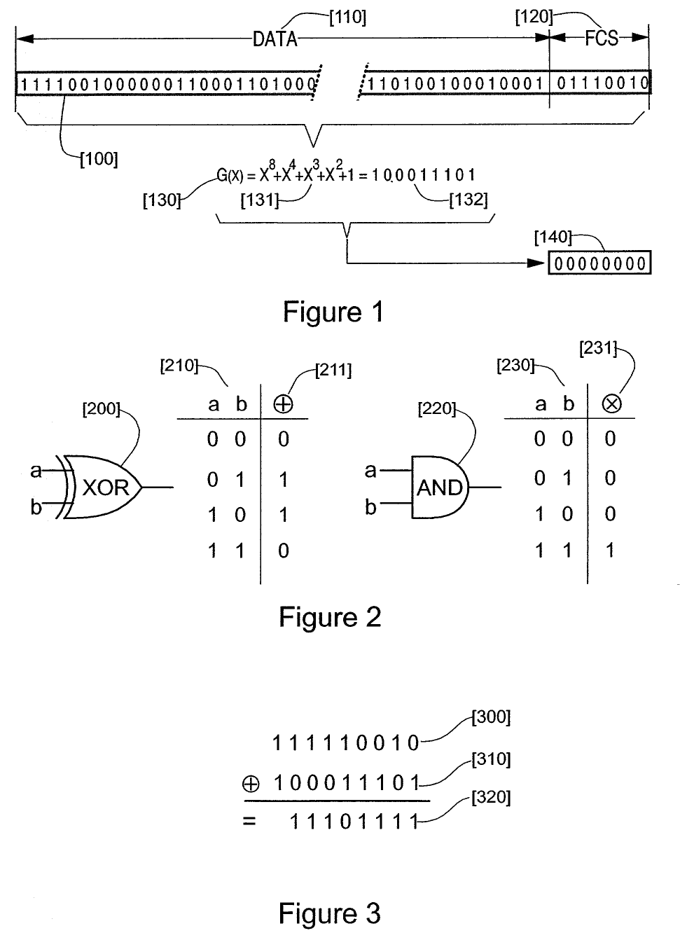

FIG. 1 illustrates the most frequent usage of CRC's (Cyclic Redundancy Check). In the field of telecommunications the exchange of binary messages [100] assumes generally that the useful content, here is broadly referred to as being the data part of the message [110], is padded with a Frame Check Sequence (FCS) field [120] for the purpose of checking its integrity en route or at receiving end. The data part may include, or not, depending on the particular communications protocols in use, not only the payload or data [110], eventually destined to the end-user, but also the various headers that may be needed to steer the message through various networks before this message reaches its final destination. Irrespective of the fact that not all of the transmitted string bits are checked or not, the end destination is expected to perform whatever checking is specified by the protocol(s) in use. To this end, most often, telecommunications protocols make use of CRC's. That is, protocol specifies a so-called generator polynomial G(x). A simple example of such a valid polynomial (even though it is not part of any known protocol or standard) is the one of degree-8 shown [130] and expressed either under the form of the powers of its non-zero terms [131] or alternatively, under the form of a binary vector [132] thus, comprised of 9 bits in this particular example. In this latter representation, ones occupy the power of X thus, are spread between 0 and 8 for this degree-8 polynomial. Then, to enable the checking, the sending end must append a FCS [120], which is the remainder of the division of the frame (considered as a large binary number) so as the receiving end, performing the same checking, must find a remainder of 0 [140] to accept it since it is the indication that the message has not been altered.

At this point of the description it must be pointed that, in practice, standards and protocols may specify a more sophisticated encoding/checking process than what is stated above. Indeed, a common practice is to start FCS computation with some form of biasing like presetting to all ones the device in charge of performing the computation (generally, a Shift Register is used to describe standards and this SR is required to be preset to all ones) and/or transmitting FCS inverted. Although, to comply with the standards, this must be eventually accommodated in one way or another this does not affect whatsoever, the invention as discussed in the rest of the description.

Also, all the operations on binary numbers used to calculate and to check the remainder are not those of the ordinary arithmetic. Rather, all computations are performed in a “polynomial arithmetic modulo two” which is further, yet briefly, discussed here after with the sole objective of better understanding the invention.

Finally, it is worth mentioning that if CRC's are mainly used in telecommunications for checking the transmission of frames they are also often used to generate a digest or signature of large files so as to ease their comparison (if two file ‘hash’ to the same signature they are likely to be identical). CRC's are even used in cryptography. For example, the encryption algorithm (though, this encryption scheme is known to be weak) built into the PKZIP data compression program (by PKWARE, Inc. 9025 N. Deerwood Drive, Brown Deer, Wis. 53223-2480, the USA) uses the following CRC of degree 32:

G(x)=X³²+X²⁶+X²³+X²²+X¹⁶+X¹²+X¹¹+X¹⁰+X⁸+X⁷+X⁵+X⁴+X²+x¹+1

This latter polynomial is used as well in telecommunications by various protocols. Among them, there are the AAL5 (Adaptation Layer 5) of ATM (Asynchronous Transfer Mode) and Ethernet i.e., the IEEE 802.3 protocol of many LANs (Local Area Network).

FIG. 2 shows the two logic (Boolean) operators that must be utilized to perform computation according to the simple arithmetic modulo two used by CRC's. All bit-wise additions must be carried out with a XOR operator [200], truth table of which [210] is marked with the addition symbol ⊕ [211] used throughout the description of the invention so as to differentiate it from the addition of ordinary numbers. Similarly, a bit-wise multiplication may have to be used. It is performed with an AND operator [220], corresponding to the right truth table [230], marked with symbol \mathring{×} [231].

FIG. 3 depicts the addition of two binary vectors [300, 310] applying, at bit level, the above described XOR operator rules. Thus, in this simple arithmetic modulo two, there is no carry to propagate and there is no difference between an addition and a subtraction. Therefore, adding (subtracting) vector [310] i.e., the 9-bit generator polynomial G(x) of FIG. 1, allows to cancel at least one (most significant) bit, on the left, in the result [320]. Indeed, all computations in the polynomial arithmetic modulo two of CRC's assume that operations on vectors must also be performed modulo the generator polynomial so as the result of any operation is reduced to a vector having, at most, a number of significant bits equal to the degree of the polynomial i.e., 8 in this example.

Addition of the generator polynomial can thus be applied recursively on vectors of any length, as many times as necessary, until result is not wider than the degree of the polynomial. Hence, obtaining a residue or remainder which is the FCS discussed in FIG. 1.

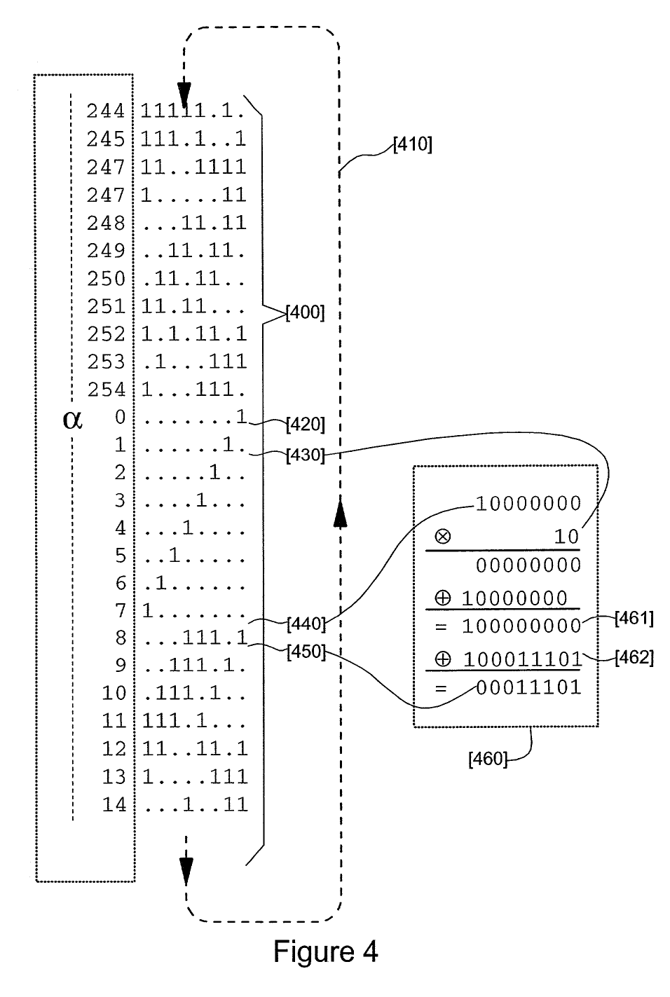

FIG. 4 further elaborates on the arithmetic modulo 2, modulo G(x), used to compute CRC's by showing how a multiplication is simply carried out. Multiplication is used here to show how a cyclic [410] (thus, finite) multiplicative group of vectors [400] can be generated with G(x). This is key to understanding CRC's. It must be noted here that, for the sake of readability, all group vectors are shown with their 0's bits replaced by a dot. Both representations of vectors (with zeros either shown as a 0 or a dot) are used in the description of the invention. However, this cannot create any confusion since it is obvious from the context which equivalent representation is used.

As with ordinary numbers there is, in the group [400] (not all vectors are shown), an identity element here noted α⁰ [420]. Every element of the finite group can be obtained from its predecessor, through a multiplication by α¹ [430], so that:

αⁿ=αⁿ\mathring{×}α¹=^{αn+1}

For example, the multiplication of α⁷ [440] by α¹ [430] so as to obtain α⁸ [450] is detailed in [460]. The multiplication is conducted in a manner similar to what is done with ordinary numbers however, with the rules for multiplication and addition previously discussed. Especially, the result of the multiplication being a 9-bit vector [461], it must be reduced to 8 by adding G(x) once [462] so as to obtain α⁸ [450]. More generally any vector can be obtained from a combination of two others as follows:

αⁿ\mathring{×}^{αp}=^{αn+p modulo e}

where e is the length (the number of elements) of the group i.e., 255 or 2⁸-1 in this example. Especially, the last element is α²⁵⁴ [470] since its multiplication by α¹ [430] returns α⁰ [420] i.e.:

α²⁵⁴\mathring{×}α¹=α^{254+1 modulo 255}=α⁰

Because G(x), the generator polynomial chosen to illustrate the invention, is a primitive irreducible polynomial (so is the one listed in FIG. 1 for the CRC-32 of ATM, Ethernet, etc..) the group of vectors generated forms a Galois field of maximum length. That is, all non-zero combinations of bits, i.e., 255 for this degree-8 polynomial (and 2³²−1 i.e., more than four billions, for the CRC-32 of FIG. 1) pertain to the field. A list of such polynomials and much more on groups, rings, fields and their algebra can be found in many books on modern algebra and, e.g., in ‘Error Correcting Codes’, 2nd edition, Peterson and Weldon, the MIT Press, 1972, Cambridge Mass., the USA.

At this stage it must be pointed out that, in practice, some standard CRC generator polynomials are not irreducible. Often, they are the product of two polynomials like the CRC-16 used by ITU-T (Telecommunication sector of International Telecommunications Union ITU, formerly CCITT) X25 protocol (a protocol suite for packet-switched networks). It specifies the use of following generator polynomial: G(x)=X¹⁶+X¹²+X⁵+1. Because this polynomial is the product of primitive irreducible polynomial: X¹⁵+X¹⁴+X¹³+X¹²+X⁴+X³+X²+X¹+1 by X¹+1 this does not permit to generate per se a Galois field. This is done in order to give to the CRC code extra error detection properties that are not however mandatory and will not be further discussed since not necessary for understanding the invention. Nevertheless, a multiplicative group, similar to [400], can be built that has all the necessary properties to fit CRC calculation. However, it is worth noting that the size of the group, in this latter case, is of 2¹⁵−1 or 32767 vectors and not 2¹⁶−1 as the degree of the polynomial would let think in a first place.

Further discussing the choices and properties of generator polynomials especially, the reasons for which some standard generator polynomial are not primitive and irreducible is far beyond the scope of the invention. This latter rather focuses on solving the practical problem of how to compute CRC's N-bit at a time. Thus, it is assumed that generator polynomials are chosen by those in charge of defining standards and protocols and that the invention is mainly aimed at proposing on one hand, a general method to expedite CRC calculation and, on the other hand, a way to determine automatically the logic necessary to achieve this objective that does not require a particular skill on CRC from the logic designer. Hence, enough has been said on the CRC way of calculating to understand, by those skilled in the art, how the invention works and can be carried out especially, to cope with the sending and receiving of messages through the very high speed telecommunication lines nowadays in use.

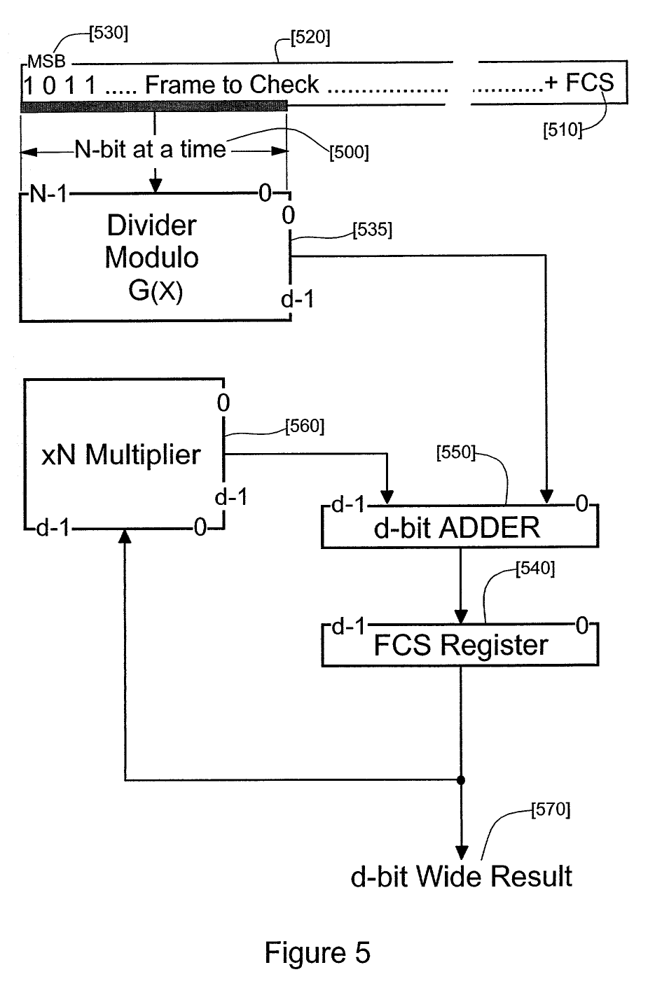

FIG. 5 discloses the computational model per the invention. This model, for computing N-bit at a time [500], works whichever generator polynomial G(x) is chosen provided a group under multiplication, as previously discussed, can be formed. G(x) is assumed to be of degree d, i.e., its higher term is Xd or, alternatively, it is represented under the form of a binary vector having d+1 terms. N is whatever value is necessary to be able to complete the job of generating a FCS [510], or checking a frame including a FCS [520] upon reception, in the imparted time. Then, frame is taken, from most significant but [530], N-bit at a time [500]. Each chunk of N-bit must thus be reduced to the size of the FCS which corresponds to d, the degree of the generator polynomial. If N is greater than d then, as explained previously, the chunk of bits must be ‘divided’ by G(x) [535] until result is, at most, d-bit wide. In other words, one must add (i.e., subtract) G(x) as many times as necessary, from the N-bit vector, until its value is modulo G(x). Obviously, if N is already equal or lower than d then, nothing more but padding 0's on the left (if d<N) to match d, is to be done. After which current value of FCS [540], multiplied [560] by a displacement corresponding to N (xN Multiplier), in the multiplicative group formed with G(x), must be added [550] so as to obtain the next current value. This loop is gone through as many times as necessary to check or generate FCS over a frame [520]. The result [570] is a d-bit wide vector result of the checking (an all zero's vector since remainder should be 0) or the FCS itself, to be padded to the transmitted frame. In practice, protocols always specify frame format so that enough room is obviously reserved to insert a FCS corresponding to G(x). Therefore, generation and checking are just about the same operation. At generation, FCS field is first blanked and result (computed with the blanks or 0's) is inserted into the reserved field before transmission. At checking, the frame to which the remainder of the division has thus been added, must return a zero value if everything has gone right en route. Again, this describes the basic process which may be somehow modified by protocols however, without bringing any fundamental change that could prevent the invention from being utilized though.

Also, it is worth noting here that determining what is MSB in a message is purely a question of definition on which all parties involved must first agree. Protocols and standard implicitly take care of this. Generally, the first transmitted of a frame is considered as being the most significant bit or MSB. Conversely, FCS, being the remainder of a division, comes last thus, occupies the least significant bits (LSB's).

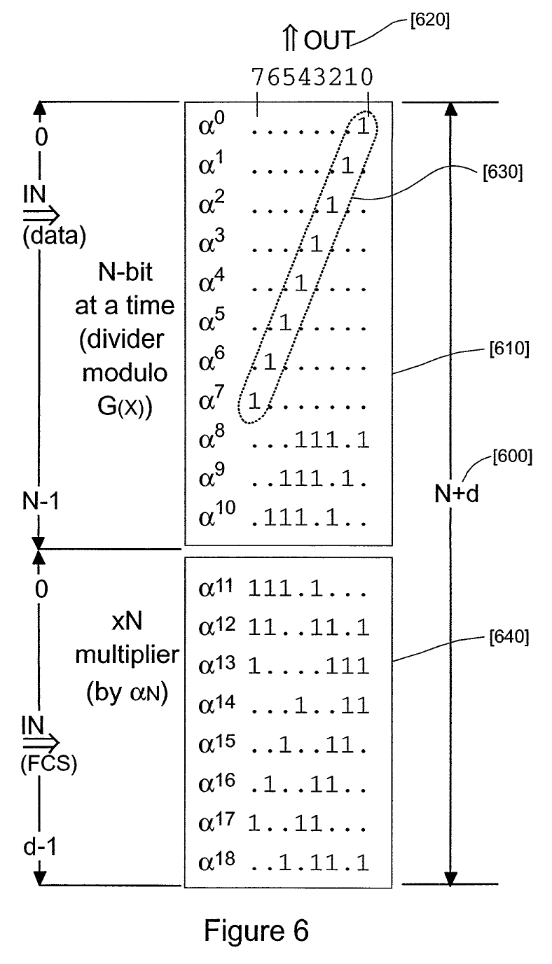

FIG. 6 shows how to determine, according to the invention, the XOR structure of multiplier and divider discussed in FIG. 5. To better exhibit the flexibility of the method example of FIG. 6 assumes that calculation must be carried out 11-bit at a time. The same degree-8 generator polynomial of FIGS. 1 and 4 is assumed. Then, the first N+d vectors [600] of the multiplicative group are computed as explained before i.e., from α⁰ to α¹⁸. The first N vectors [610] allow to build the divider modulo G(x) so that an 11-bit input vector (applied to the 11 rows α⁰ to α¹⁰) are reduced to 8 bits (along the columns 0-7) [620] as follows:

OUT bit(0): IN bit(0) ⊕IN bit(8)

OUT bit(l): IN bit(1) ⊕IN bit(9) OUT

bit(2): IN bit(2) ⊕IN bit(8) IN bit(10)

OUT bit(3): IN bit(3) ⊕IN bit(8) ⊕IN bit(9)

OUT bit(4): IN bit(4) ⊕IN bit(8) ⊕IN bit(9) ⊕IN bit(10)

OUT bit(5): IN bit(5) ⊕IN bit(9) ⊕IN bit(10)

OUT bit(6): IN bit(6) ⊕IN bit(10)

OUT bit(7): IN bit(7)

It should be obvious to those skilled in the art that, if N is chosen to be equal or lower than degree of polynomial (d) then, only the first vectors of the multiplicative group, that forms a diagonal matrix [630], need to be considered. In which case there is a one to one correspondence between the IN and OUT bits thus, actually, there is no division to be done. This is just another way of saying that, if input vector is already equal or lower than the degree of the generator polynomial then, the division modulo G(x) is a trivial operation in the mathematical sense of the term.

Similarly, multiplier by N is built from rows α¹¹ to α¹⁸ [640] so that current value of FCS register is multiplied by a displacement, in the multiplicative group, corresponding to N (11 in this example) before next chunk of data modulo G(x) can be added. Multiplier is thus always a d-square matrix. This is an 8×8 matrix [640] corresponding to following table in this example where G(x) is a degree-8 polynomial.

OUT bit(0): IN bit(12) ⊕IN bit(13) ⊕IN bit(14) ⊕IN bit(18)

OUT bit(1): IN bit(13) ⊕IN bit(14) ⊕IN bit(15)

OUT bit(2): IN bit(12) ⊕IN bit(13) ⊕IN bit(15) ⊕IN bit(16) ⊕IN bit(18)

OUT bit(3): IN bit(11) ⊕IN bit(12) ⊕IN bit(16) ⊕IN bit(17) ⊕IN bit(18)

OUT bit(4): IN bit(14) ⊕IN bit(17)

OUT bit(5): IN bit(11) ⊕IN bit(15) ⊕IN bit(18)

OUT bit(6): IN bit(11) ⊕IN bit(12) ⊕IN bit(16)

OUT bit(7): IN bit(11) ⊕IN bit(12) ⊕IN bit(13) ⊕IN bit(17)

It must be noted that computing N-bit at a time implicitly assumes that the frame must be a multiple of N. If it were not the case then it must be padded with enough MSB bits when starting computation. This should be definitively the case if, as suggested in this example, computation is done (a weird) 11-bit at a time. Obviously, in practice, frames are often made of complete bytes, half-word (16 bits) or even full-word (32 bits) and it seems convenient that computation be carried out with such numbers or multiple of even though the invention allows to cope with any value of N.

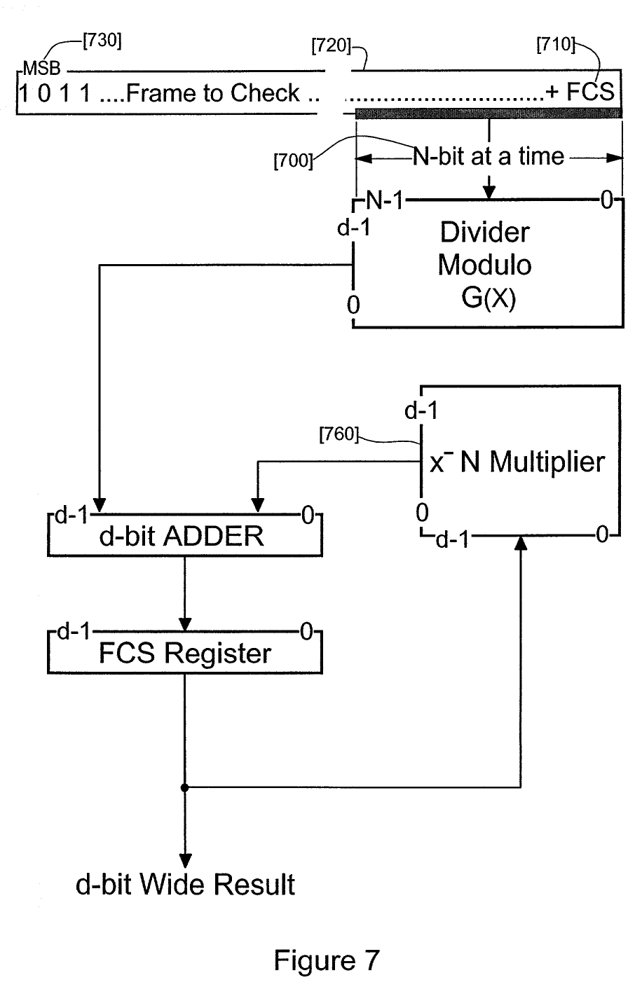

FIG. 7 discusses another advantage of using the invention. If, for whatever reason, computation must start from FCS i.e., from the ‘end’ of the message or from the ‘bottom’ of a file so that FCS [710] is available first and checking must end with MSB [730] of frame [720] a simple modification to the scheme of the invention can be brought. It just consists in moving backward in the multiplicative group, by step of N, thus requiring the use of a xN Multiplier [760] instead of the forward xN Multiplier of FIG. 5. This is the only change which is necessary to accommodate a backward checking.

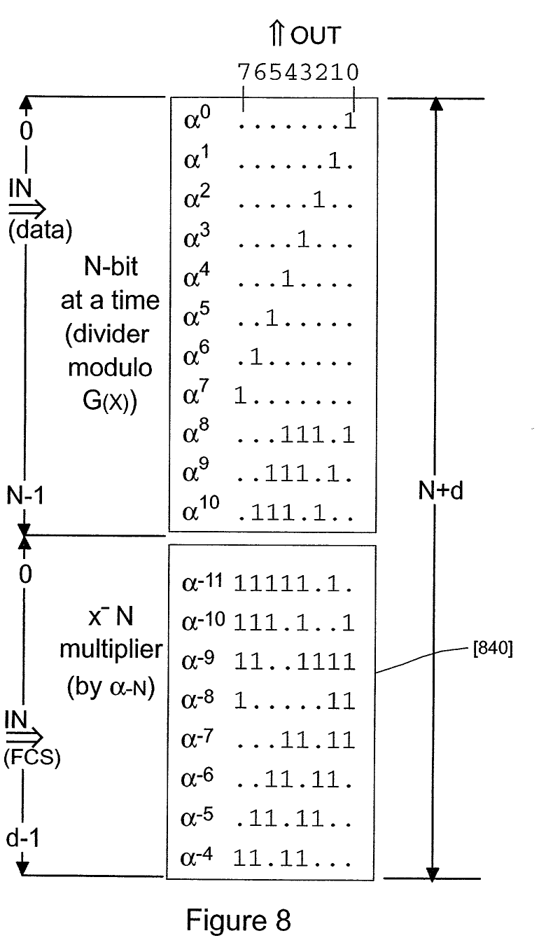

FIG. 8 is thus the counterpart of FIG. 6 for allowing a backward computation. Therefore, only multiplier [840] is changed now including the 8 vectors of the multiplicative group from α⁻¹¹ to α⁻⁴. Because the group of vectors is, as discussed in FIG. 4, finite and cyclic the 8 vectors corresponding to the range α⁻¹¹ to α⁻⁴ are in fact vectors α²⁵⁵⁻¹¹ to α²⁵⁵⁻⁴ i.e., α²⁴⁴ to α²⁵¹ already shown in FIG. 4.

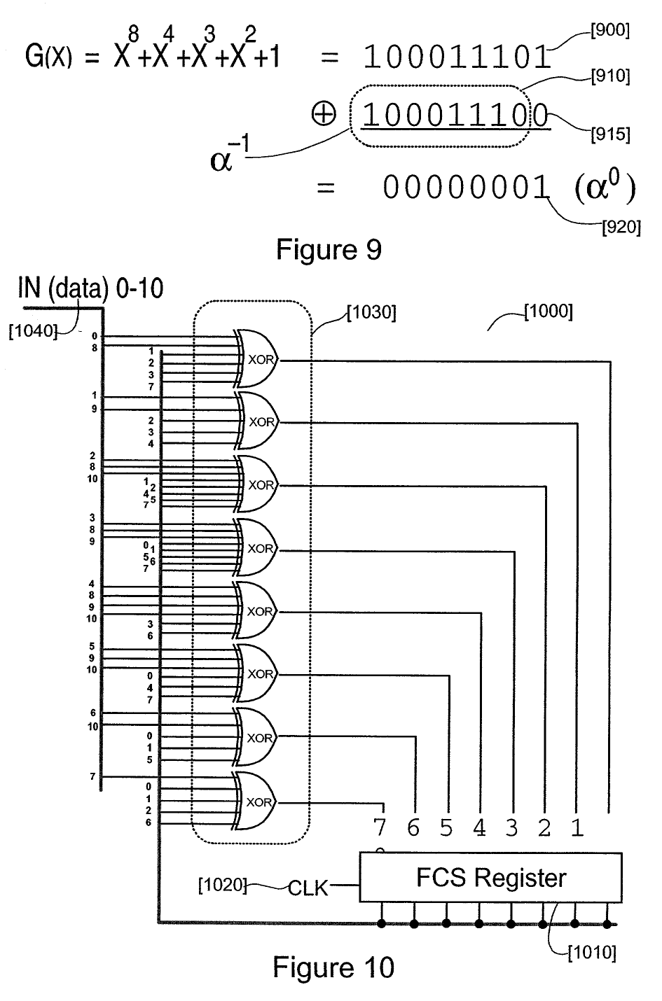

FIG. 9 explains how the negative powers of α can be generated so as to build a x⁻N Multiplier per the invention. Indeed, with generator polynomial having large values of d, the number of elements of the group can be very high e.g., 2³²−1 (more than four billions) for the standard CRC-32 mentioned in FIG. 1. Therefore, it must be possible to generate the first (i.e., counting backward) negative values of α without having to generate all the vectors of the group or even knowing their number. This is simply achievable by noticing that the last vector of the group or α⁻¹ [910] can always be deduced directly from G(x) itself [900] since its addition this latter, once multiplied by α⁻¹, i.e.: 1 0 (which corresponds to the padding of one zero on the right) [915], must return the first vector of the group α⁰ [920], i.e.: 1 (the identity element) because group is a finite cyclic group. Once α⁻¹ has been determined it is trivial to generate recursively, in a manner similar to what has been explained in FIG. 4 (thus, counting backward in the multiplicative group), enough negative powers of α so as to be able to build the x⁻N Multiplier discussed in FIG. 7 and 8. Hence, α⁻²=α⁻¹α⁻¹, etc. Again, α⁻¹ corresponds to α²⁵⁴, α⁻² to α²⁵³ in this particular example (as shown in FIG. 4) and so on.

FIG. 10 shows a possible implementation of the state machine [1000] of FIG. 5, logic of which is implemented here under the form of 8 n-way XORs [1030]. Data divider and FCS multiplier of FIG. 5 are thus actually merged into the same block of logic [1030] feeding a FCS register [1010] updated at each cycle of a clock [1020]. Therefore, eleven new bits of the frame to be checked [1040] are inputted, at each cycle, into the state machine. This example of implementation uses what is conceptually depicted in FIG. 6.

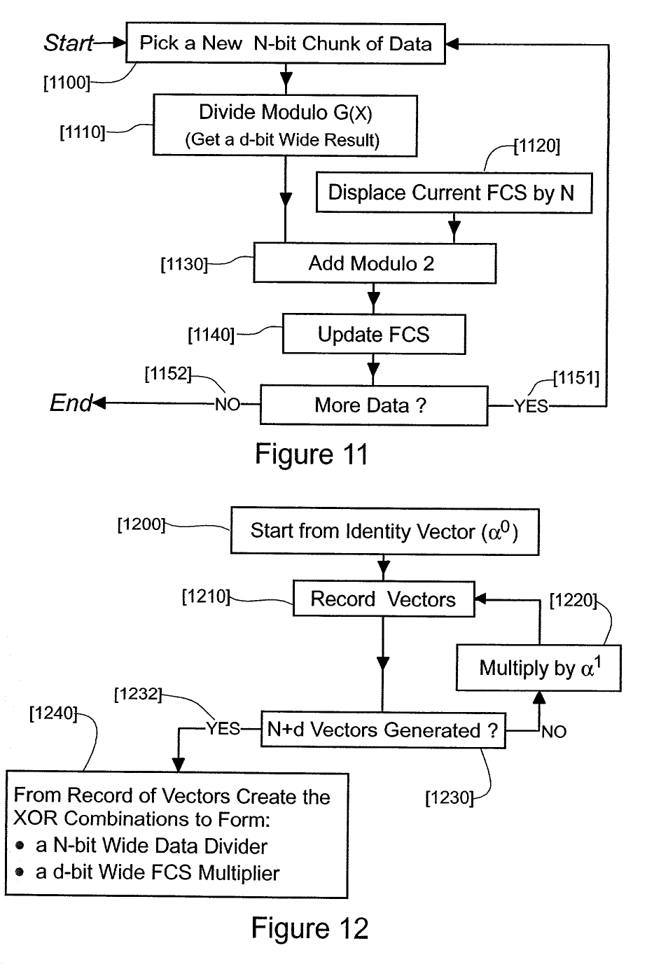

FIG. 11 shows the steps of the method for computing, N-bit at a time, according to the invention. Computation starts or resume at step [1100] when a first or a subsequent chunk of N-bit is picked from the piece of data e.g., a frame, to be checked or encoded before transmission. Then, the N-bit wide chunk is divided modulo G(x) [1100] so as result matches the degree (d) of the generator polynomial. An actual division need to be performed only if N is larger than d. If equal, nothing is to be done i.e., the N-bit wide chunk of data is used as is. If lower, the N-bit chunk of data, used as is, must also be left justified i.e., padded with enough zeros to match the size of the d-wide adder. The above is not different from the division of regular integers where if dividend is already equal or lower than divider then, nothing specific is to be done. While performing division (or sequentially) the current value of FCS, considered as a vector of the multiplicative group that can be formed with G(X), is multiplied as it is displaced by a value corresponding to N [1120] in the multiplicative group. Both are added [1130] and result used to update FCS [1140] which becomes the current value. If more data are to be processed [1151] method resumes at step [1100] with N more bits entering the state machine. If not, loop is exited [1152]. Result of the checking or the pattern of bits to update FCS field is therefore available in FCS register.

FIG. 12 shows the steps of the method for generating automatically the structure of the divider and multiplier needed to perform a forward computation (from MSB) of CRC's. It starts [1200] from the identity vector (α⁰) of the multiplicative group. All vectors are recorded [1210] while successively multiplied by α¹ [1220] so as to obtain the N+d vectors [1230] required to form the divider and the multiplier necessary to carry out the invention. When enough vectors are recorded [1232] they are eventually used [1240] for synthesizing the corresponding logic of XOR's.

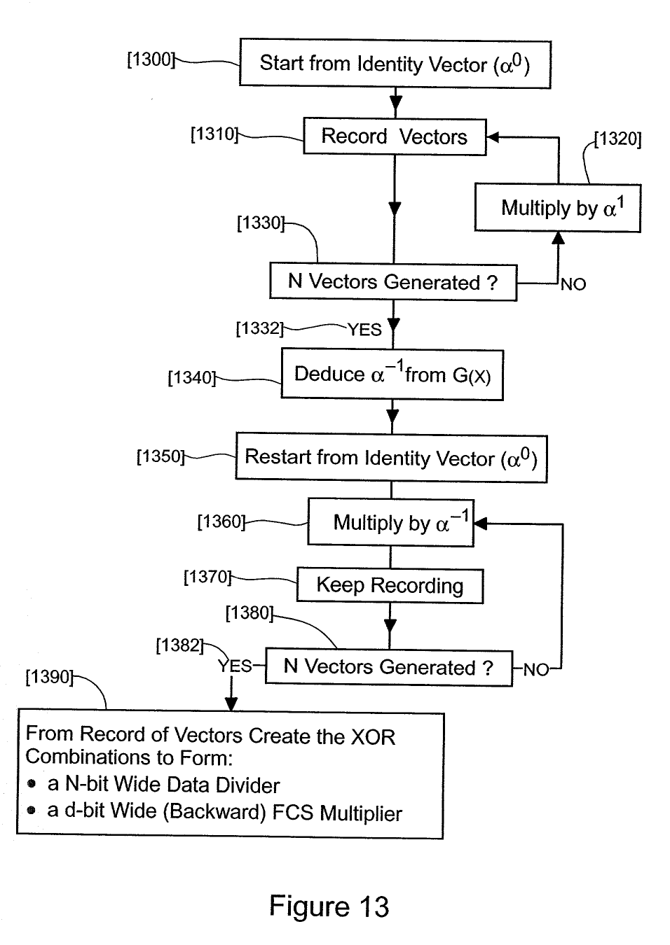

FIG. 13 shows the steps of the method for generating automatically the structure of the divider and multiplier needed to perform a backward computation (from LSB) of CRC's. The first part is identical to FIG. 12. That is, computation of vectors start from α⁰ [1300]. N ‘positive’ vectors are generated by successive multiplication's [1320] by α¹. All vectors are recorded [1310]. When enough vectors (N) for the divider have been obtained [1332] (identical to the ones of FIG. 12) those for the x⁻N Multiplier are generated in turn from α⁻¹ after the last vector of the group has been deduced from G(x) [1340] so as, by successive multiplication of α⁻¹ [1360], restarting from α⁰ [1350], N ‘negative’ vectors are generated [1380] and recorded [1360]. When done [1382], like in FIG. 12, vectors are used [1390] for synthesizing the corresponding logic of XOR's especially, implementing in this case, a backward FCS multiplier in place of the forward multiplier of FIG. 12.

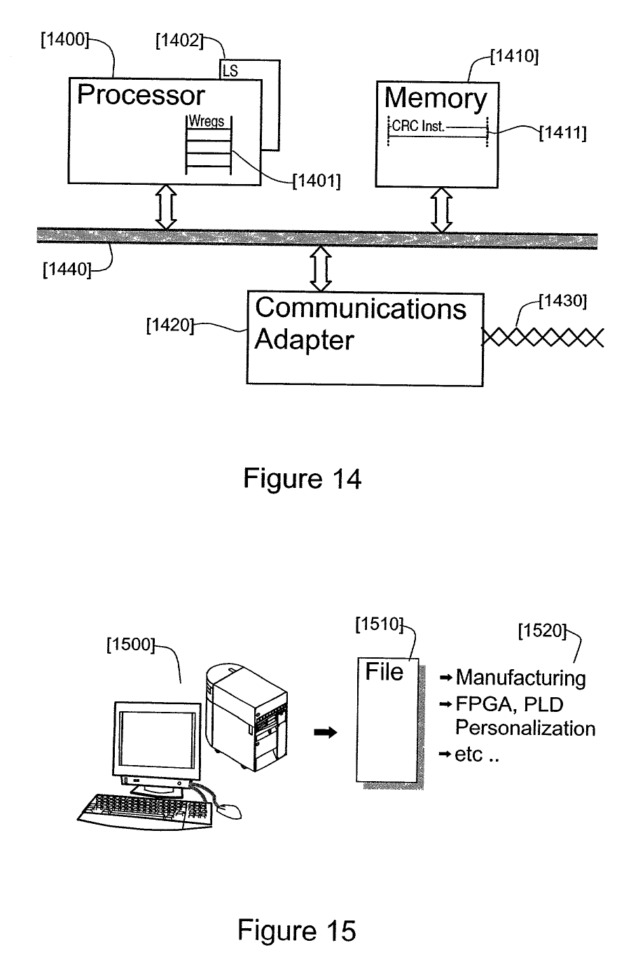

FIG. 14 shows a typical system according to the invention. It is comprised of a processor [1400] capable of executing instructions from a main memory [1410] and, a communications adapter [1420] interfacing a telecommunications line e.g., a high speed fiber optic line [1430]. Processor, memory and communications adapter are all connected on a common system bus [1440] so that they can communicate. Then, frames sent or received through the line [1430] and communications adapter [1420] (aimed at adapting the communications protocol), while stored e.g., in processor memory, can have their FCS checked or generated. To this end, processor is devised to be able to execute one or more specialized ‘CRC’ instructions [1411], carrying out the action of divider and multiplier per the invention. Typically those CRC instructions, part of a program, are executed over current content of internal working registers [1401], and/or local store directly attached to the processor [1402] and aimed at temporarily holding the current part of the data frame on which computation is being performed. Typically, a working register or a local store memory address can play the role of the FCS register previously discussed. Hence, this approach of the invention assumes that checking and generation of FCS is done through the execution of a program over a processor having specialized instructions in order to speed up the process of handling frames received or transmitted over a communication line [1430].

FIG. 15 illustrates another application of the invention where a computer, typically a work station [1500] of the kind used to design and simulate integrated circuits, is utilized to synthesize logic from a high level description of it. This high level description is often the popular VHDL (Very high speed integrated circuit Hardware Description Language) design language, with Ada-like syntax, for VLSI (Very Large Scale Integration) type of components. Whichever design language is used, design software running on the work station is assumed to be devised to generate automatically the circuitry according to a high level description done by the designer. Then, the invention and more specifically the methods of FIGS. 12 and 13 are assumed to be used, so as to obtain the logic, corresponding to a CRC and a particular generator polynomial, to allow computation N-bit at a time. This, without requiring any particular skill on CRC from the circuit designer other than choosing the CRC polynomial (anyway, generally imposed by a protocol or standard) and the number of bits to process at each loop. Therefore, in this type of application, invention participates to the generation of an interface file [1510] aimed at describing a part so as it can be eventually manufactured [1520]. Yet, in other applications, file can be used to personalize a Field Programmable Gate Array (FPGA) or any form of Programmable Logic Device (PLD) often used to implement logic function.

What is claimed is:

1. A method of performing a Cyclic Redundancy Check (CRC) calculation, said CRC calculation done with N-bit at a time [500] over a binary string of data bits [520], said CRC calculation based on a generator polynomial G(x) [130] of degree d [131], said CRC calculation having intermediate and final results fitting a d-bit wide Field Check Sequence (FCS) [120], said generator polynomial allowing to form a multiplicative cyclic group comprised of d-bit wide binary vectors [400], said method comprising the steps of:
picking [1100] a new N-bit chunk of data bits from said binary string of data bits;
dividing [1110], modulo said generator polynomial G(x), said new N-bit chunk of data bits thus, getting a d-bit wide division result [535];
displacing [1120], in said multiplicative cyclic group, a current value of said d-bit wide FCS, considered as one of said d-bit wide binary vectors, of a value corresponding to said N-bit at a time;
adding [1130], modulo two, said d-bit wide division result and said displaced d-bit wide FCS;
updating [1140] said d-bit wide FCS;
checking if more data bits of said binary string of data bits are left for calculation:
if yes [1151], resuming calculation loop at picking step;
if not [1152], exiting calculation loop; thereby, getting a final result of said CRC calculation in said d-bit wide FCS.

2.The method according to claim 1 wherein said final result is utilized to generate said d-bit wide FCS [510] for said binary string of data bits.

3. The method according to claims 1 or 2 wherein said final result is a checking result of said binary string of data bits [520] including said d-bit wide FCS [510].

4. The method according to claim 1 wherein said dividing step is replaced, if value of said N-bit is equal to said degree d, by the step of:
handling directly [630] said new N-bit chunk of data bits as if it is said d-bit wide division result [535].

5. The method according to claim 4 wherein said handling step includes, if value of said N-bit is lower than said degree d, the further step of:
padding said new N-bit chunk of data with enough leading zeros to match said d-bit wide FCS [540].

6. The method according to claim 1 wherein said CRC calculation is done from a most significant bit (MSB) [530] of said binary string of data bits and wherein said displacing step includes a forward multiplication [560] of said d-bit wide FCS.

7. The method according to claim 1 wherein said CRC calculation is done from a least significant bit (LSB) [710] of said binary string of data bits and wherein said displacing step includes a backward multiplication [760] of said d-bit wide FCS.

8. The method according to claim 1 wherein said binary string of data bits is a frame or message moved over a communications network.

9. The method according to claim 1 wherein said binary string of data bits is derived or stored as a file in a computing system.

10. A method for generating a combinational logic block [1030] implementing a Divider Modulo G(x) [535] and a xN Multiplier [560], said Divider Modulo G(x) and said xN Multiplier to permit a forward calculation be done said N-bit at a time on the basis of said generator polynomial G(x) of degree d, said method comprising the steps of:
starting [1200] from an identity vector (α⁰) [420] part of said multiplicative group [400] formed of said d-bit wide binary vectors with said generator polynomial G(x) of degree d;
recording [1210] said d-bit wide binary vector;
checking [1230] if at least N+d of said d-bit wide binary vectors have been generated;
if not:
multiplying [1220] a last recorded of said d-bit wide binary vector by a second d-bit wide binary vector (α¹) [430] part of said multiplicative group [400];
resuming at said recording step [1210];
if yes [1232]:
creating [1240] said Divider Modulo G(x) and said xN Multiplier out of said at least N+d d-bit wide binary vectors;
thereby, obtaining said combinational logic block.

11. A method for generating a combinational logic block implementing a Divider Modulo G(x) and a x⁻N Multiplier [760], said Divider Modulo G(x) and said x⁻N Multiplier to permit that backward calculations be done said N-bit at a time on the basis of said generator polynomial G(x) of degree d, said method comprising the steps of:
starting [1300] from said identity vector (α⁰) [420] part of said multiplicative group [400] formed of said d-bit wide binary vectors with said generator polynomial G(x) of degree d;
recording [1310] said d-bit wide binary vector;
checking [1330] if at least N of said d-bit wide binary vectors have been generated;
if not:
multiplying [1320] said last recorded of said d-bit wide binary vector by said second d-bit wide binary vector (α¹) [430] part of said multiplicative group [400];
resuming at said recording step [1310];
if yes [1332]:
deducing [1340] a last d-bit wide binary vector (α⁻¹) [910] part of said multiplicative group;
restarting [1350] from said identity vector (α⁰) [420];
multiplying [1360] by said last d-bit wide binary vector (α⁻¹);
keep recording [1370] said d-bit wide binary vector;
checking [1380] if at least N new of said d-bit wide binary vectors have been generated;
if not:
resuming at said multiplying by said last d-bit wide binary vector (α⁻¹) step [1360];
if yes [1382]:
creating [1390] said Divider Modulo G(X) and said x⁻N Multiplier out of said at least N d-bit wide binary vectors and said at least N new d-bit wide binary vectors;
thereby, obtaining said combinational logic block.

12. A system, in particular a processor [1400], executing instructions for carrying out CRC calculations according to the method of any one of the claims 1 to 9.

13. A system, in particular a state machine [1000] aimed at performing CRC calculations N-bit at a time, comprising means adapted for carrying out the method according to any one of the claims 1 to 9.

14. A system, in particular a work station [1500], comprising means adapted for generating a logic block according to the methods of claims 10 or 11.

15. A computer-like readable medium comprising instructions for carrying out the methods according to any one of the claims 1 to 11.

16. A method for calculating Cyclic Redundancy Check (CRC) including the acts of:
(a) selecting N-bits, N greater than 1, of data from a binary string of data bits;
(b) displaying (1120) in a multiplicative cyclic group of values corresponding to N a current value of d-bit wide FCS, considered as one of the d-bit wide binary vectors;
(c) adding (1130) modulo two, the N-bits and said displaced d-bit wide FCS; and
(d) updating said d-bit wide FCS.

17. The method of claim 16 further including the acts of:
(e) checking if more bits of said binary string are left for calculation;
(f) if yes, repeating acts (a) through (e);
(g) if not, existing with result in act (d) being the calculated CRC.

18. The method of claims 16 or 17 further including the step of prior to performing step (b) dividing the N-bits, modulo generator polynomial G(x), to obtain a d-bit wide division result.
